(19) United States
(12) Patent Application Publication
(10) Pub. No.: US 2009/0309163 A1
(43) Pub. Date: Dec. 17, 2009

(54) METHOD AND STRUCTURE FOR ENHANCING BOTH NMOSFET AND PMOSFET PERFORMANCE WITH A STRESSED FILM AND DISCONTINUITY EXTENDING TO UNDERLYING LAYER

(75) Inventors: Jing Wang, Fishkill, NY (US); Huilong Zhu, Poughkeepsie, NY (US)

Correspondence Address: HOFFMAN WARNICK LLC, 75 STATE ST, 14TH FL, ALBANY, NY, 12207, US

(73) Assignee: INTERNATIONAL BUSINESS MACHINES CORPORATION, Armonk, NY (US)

(21) Appl. No.: 12/136,970

(22) Filed: Jun. 11, 2008

(51) Int. Cl. H01L 27/092; H01L 21/31

(52) U.S. Cl. 257/369; 438/424; 257/E27.062; 257/E21.24

(57) ABSTRACT

A structure and method for making includes adjacent pMOSFET and nMOSFET devices in which the gate stacks are each overlain by a stressing layer that provides compressive stress in the channel of the pMOSFET device and tensile stress in the channel of the nMOSFET device. One of the pMOSFET or nMOSFET device has a height shorter than that of the other adjacent device, and the shorter of the two devices is delineated by a discontinuity or opening in the stressing layer overlying the shorter device. In a preferred method for forming the devices a single stressing layer is formed over gate stacks having different heights to form a first type stress in the substrate under the gate stacks, and forming an opening in the stressing layer at a distance from the shorter gate stack so that a second type stress is formed under the shorter gate stack. In an exemplary embodiment, the opening may be extended into an underlying layer such as a source/drain region of the shorter gate stack and a bottom thereof silicided such that a contact formed therein exhibits reduced contact resistance.

### BACKGROUND

The present invention relates generally to semiconductor device processing techniques, and, more particularly, to a method and structure for improving CMOS device performance and reliability by using single stress liner instead of dual stress liner.

More recently, dual stress liner (DSL) techniques have been introduced in order to provide different stresses in P-type MOSFET devices with respect to N-type MOSFET devices. For example, a nitride liner of a first type is formed over pMOSFETs of a CMOS device, while a nitride liner of a second type is formed over the nMOSFETs of the CMOS device. More specifically, it has been discovered that the application of a compressive stress in a pMOSFET channel in the direction of the electrical current improves carrier, hole, mobility therein, while the application of a tensile stress in an nMOSFET channel improves carrier, electron, mobility therein. Thus, the first type nitride liner over the pMOSFET devices is formed in a manner so as to achieve a compressive stress, while the second type nitride liner over the nMOSFET devices is formed in a manner so as to achieve a tensile stress.

For such CMOS devices employing dual liners, the conventional approach has been to form the two different nitrides using separate lithographic patterning steps. In other words, for example, the first type nitride liner is formed over both pMOSFET and nMOSFET devices, with the portions of the first type nitride liner over the nMOSFET devices being thereafter patterned and removed. After an optional formation of an oxide layer, the second type nitride liner is formed over both regions, with a second patterning step being used to subsequently remove the portions of the second type nitride liner over the pMOSFET devices. Unfortunately, due to inherent inaccuracies associated with aligning lithographic levels to previous levels, the formation of the two liners could result in a gap or underlap there between. In particular, this gap will cause problems for subsequent etching of holes for metal contact vias since, during the etching, the silicide in the underlap/gap areas will be over etched. This in turn will increase sheet resistance of the silicide.

On the other hand, the two liners could also be formed in a manner such that one liner overlaps the other. In fact, the reticles used for the two separate patterning steps are typically designed to ensure an overlap such that there is no gap between the two liner materials. However, having certain regions with overlapping nitride liners creates other problems with subsequent processing due to issues such as reliability and layout inefficiencies. For example, a reactive ion etch (RIE) process for subsequent contact formation may have to accommodate for a single-thickness liner in some areas of the circuit, while also accommodating for a double-thickness (overlapping) liner in the interface areas. Moreover, if such overlapping areas are excluded from contact formation, a restriction results in terms of available layout area and critical dimension (CD) tolerances. The overlap will also cause problems during subsequent etching of holes for metal contact vias since, during the etching, all of the silicide will be over etched except for the silicide under the overlap areas. This can increase sheet resistance and junction leakage of devices.

U.S. Pat. Nos. 7,183,613 and 7,326,997 disclose method and structure for enhancing both NMOSFET and PMOSFET performance with a stressed liner.

### SUMMARY

The foregoing discussed drawbacks and deficiencies of the prior art are overcome or alleviated by a method for forming a single stress liner for a complementary metal oxide semiconductor (CMOS) device. In an exemplary embodiment, the method includes: 1) forming a CMOS structure having an nMOSFET and pMOSFET with different gate heights (for example, the nMOSFET gate may be lower than the gate of the pMOSFET, or vice versa), 2) depositing a single stress liner of a either compressive or tensile stress over both the nMOSFET and pMOSFET; and 3) etching part of the stress liner close to the shorter of the gates to form stress of the opposite type in the channel of the shorter gate. For example, if a compressive stress liner is first formed, and the shorter gate is the nMOSFET, then etching part of the compress stress liner in proximity to the nMOSFET will result in tensile stress in the channel of the nMOSFET. If the shorter gate is the pMOSFET, then according to the invention, a tensile stress liner is deposited over both gates, and part of the stress liner is removed around the shorter pMOSFET, resulting in compressive stress in the channel of the pMOSFET.

In addition, in another exemplary embodiment, the above-described embodiment may further include extending the etching of the stress liner to form an opening into a source/drain region of the second gate stack, forming a silicide region in a bottom of the opening, and forming a contact in the opening. Consequently, the required stresses as described above are formed along with a low contact resistance, stress liner discontinuity forming contact. In another exemplary embodiment, the above-described embodiment may further include extending the etching of the stress liner to form an opening at least partially into an isolation region or partially into an isolation region and partially into a source/drain region of the second gate stack.

### BRIEF DESCRIPTION OF THE DRAWINGS

Referring to the exemplary drawings wherein like elements are numbered alike in the several Figures:

FIGS. 1 through 10C illustrate steps of an exemplary process flow for forming an nMOSFET and a pMOSFET, wherein one gate stack is shorter in height than the other, in accordance with an embodiment of the invention;

FIG. 11 illustrates a plot of stress as a function of horizontal distance Lcut from the gate conductor having a shorter height to the edge of the opening in the stressing layer formed in accordance with the invention; and

FIGS. 12 through 17 illustrate additional steps subsequent to FIGS. 10A-C of an exemplary process flow for forming an nMOSFET and a pMOSFET, wherein one gate stack is shorter in height than the other, in accordance with an embodiment of the invention.

### DETAILED DESCRIPTION

Disclosed herein is a method and structure for improving CMOS device performance and reliability by using single stress silicon nitride liner for both nMOSFET and pMOSFET. Briefly stated, the embodiments disclosed herein result in compressive stress in the pMOSFET channel and tensile stress in the nMOSFET channel on the same chip or integrated circuit (IC) by using the same stressed film to cover both the pMOSFET and the nMOSFET. This results in performance enhancement due to local stress for both nMOSFET and pMOSFET, without causing misalignment problems.

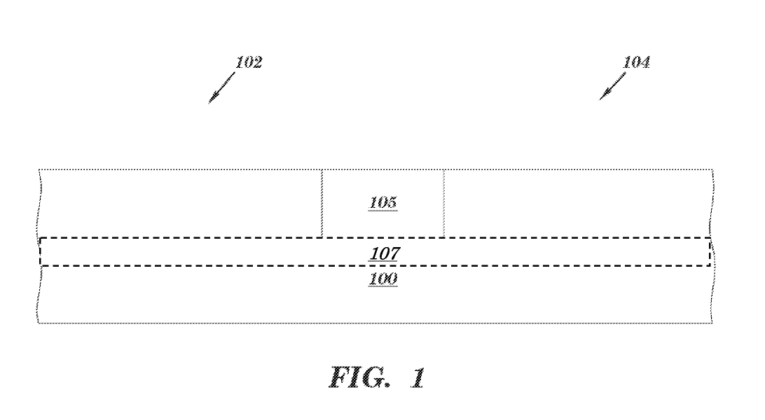

Referring initially to FIG. 1, there is shown a cross sectional view of a semiconductor substrate 100 having an nMOSFET device region 102 and a pMOSFET device region 104 separated by an isolation region 105 formed therein, such as a shallow trench isolation (STI). In an alternative embodiment, the teachings of the disclosure may also be applied relative to a semiconductor-on-insulator substrate, which may additionally include a buried insulator layer 107, e.g., of silicon oxide. For clarity purposes, the remainder of the disclosure omits buried insulator layer 107.

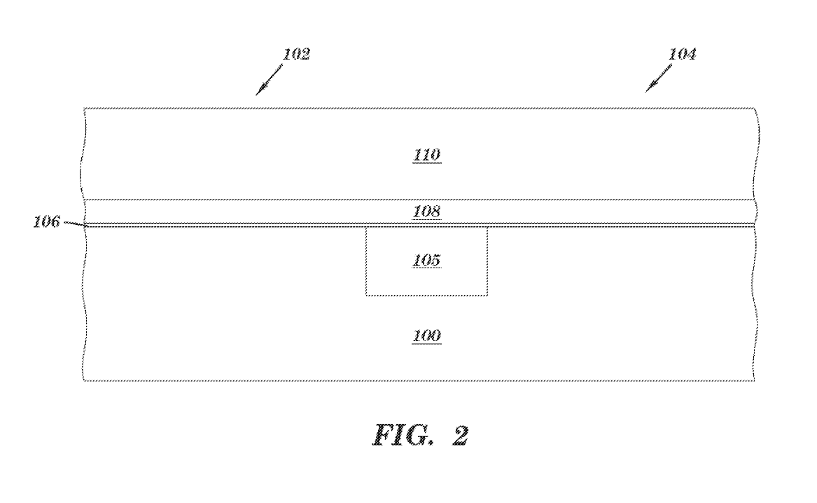

Referring to FIG. 2, a gate dielectric layer 106 is formed over the substrate 100 including the isolation region 105. The gate dielectric 106 may be any suitable dielectric material, such as silicon dioxide. The gate dielectric 106 may be formed, for example, by thermal oxidation or deposition of a high K material, such as HfO₂, ZrO₂, Al₂O₃, TiO₂, La₂O₃, SrTiO₃, LaAlO₃, and mixtures thereof. The gate dielectric 106 typically has a thickness in the range of about 0.8-8 nm. In accordance with the invention, a first layer of a gate conductor 108 is formed atop the gate dielectric layer 106. The first gate conductor layer 108 may be any suitable gate conductor material such as polysilicon, W, WN, TiN, TaN, TaAlN, Ta or SiGe, more typically polysilicon. For gate lengths of 35-45 nm, the polysilicon layer 108 is preferably 10-30 nm thick. A second gate conductor layer 110 having an etch rate different than the first gate conductor layer 108, such as polysilicon-germanium (poly-SiGe), if the first conductor layer is polysilicon, is deposited atop the first gate conductor (e.g. polysilicon) layer 108. For gate lengths of 35-45 nm, the poly-SiGe layer 110 is preferably 70-90 nm thick. Preferably, the second gate conductor layer 110 is thicker than the first conductor layer 108.

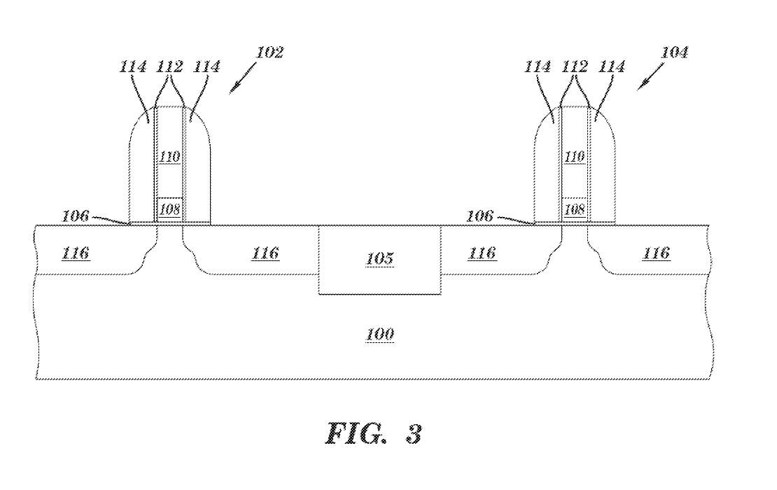

Referring to FIG. 3, devices 102, 104 are formed by processes now known or developed in the future. For example, the gate stacks may be formed by patterned etching, formation of spacers including optional thin oxide liners 112 and nitride spacers 114, and implantation to form source/drain halo regions and extensions 116, followed by source/drain anneal, as will be recognized by one skilled in the art.

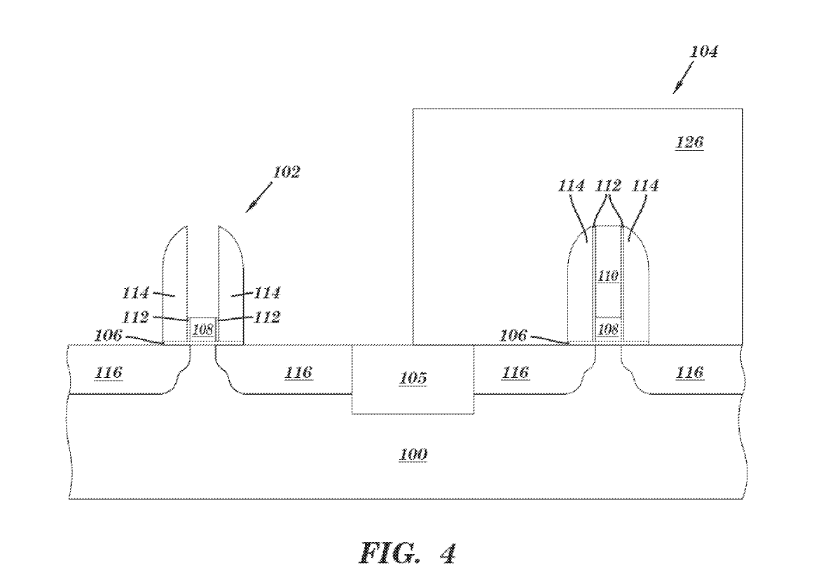

Referring to FIG. 4, the pMOSFET 104 is covered by a mask such as photoresist layer 126. Then, the second gate conductor layer 110, e.g., the poly-SiGe layer, is removed from the first gate conductor layer 108 in the nMOSFET 102, for example, by an etch process selective to silicon, poly Si, oxide and nitride. Then, the exposed oxide liner 112 above the first gate conductor 108 is removed from the sidewalls 114 of the nMOSFET 102, for example, using a process such as buffered HF (BHF). Etch time will depend on the thickness of the oxide liner 112. Since the oxide liner 112 is very thin, for example, on the order of about 5-10 nm, there will be no significant damage to the isolation region 105.

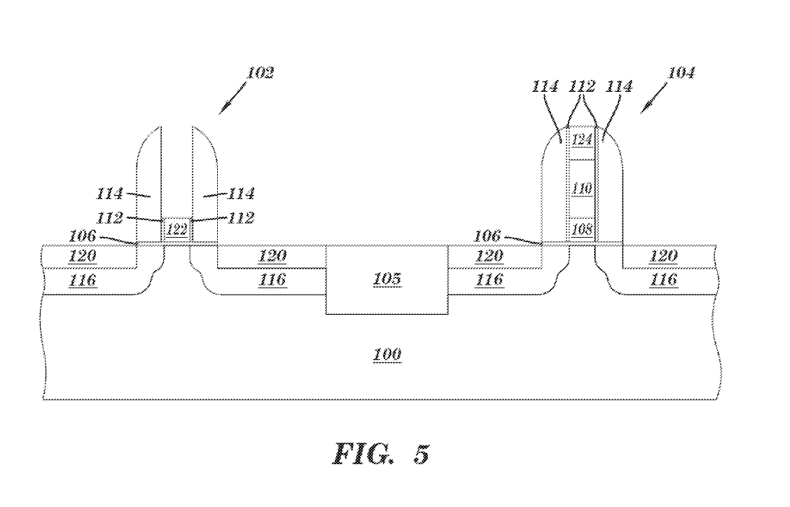

Referring to FIG. 5, the photoresist 126 is removed. Then, a metal layer is deposited over the structure. For example, in a preferred embodiment, nickel is deposited at a thickness between about 3-20 nm, sufficient to fully silicide the polysilicon layer 108 in the nMOSFET gate stack 102. After an anneal, for example, at 300-500° C. at 1-60 seconds, a semiconductor metal alloy is formed from the metal and the silicon of the nMOSFET gate stack 102, the silicon of the substrate 100, and the SiGe of the pMOSFET gate stack 104. The resulting structure includes silicide regions 120 over the source/drain regions 116, a fully silicided gate conductor 122 in the nMOSFET 102, and a silicided top portion 124 of the pMOSFET 104.

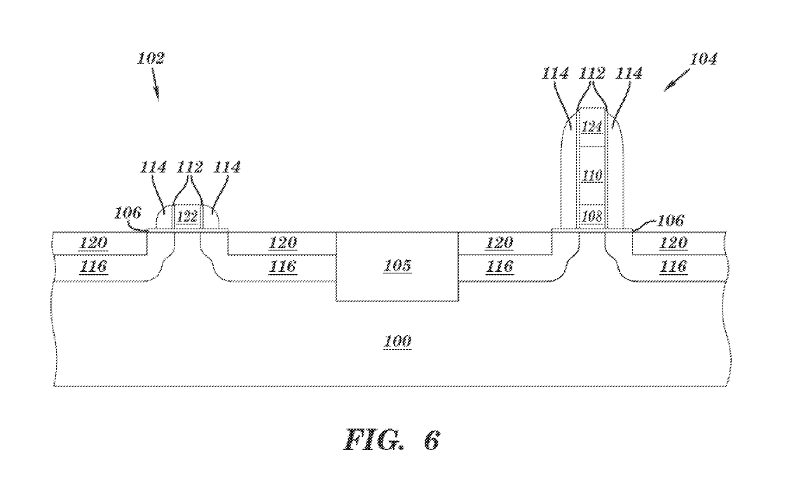

Next, as shown in FIG. 6, the nitride spacers 114 are etched back, for example by a wet etch or dry etch process, so that the nitride spacers 114 have substantially the same height as the silicided gate conductor 122 and oxide liner 112 of the nMOSFET 102, resulting in an nMOSFET gate stack 102 that is shorter in height than the pMOSFET gate stack 104. Since a wet etch process is isotropic, the nitride spacers 114 on the pMOSFET 104 will be thinned. Preferably, the nitride spacers 114 are thinned no more than about half its original thickness.

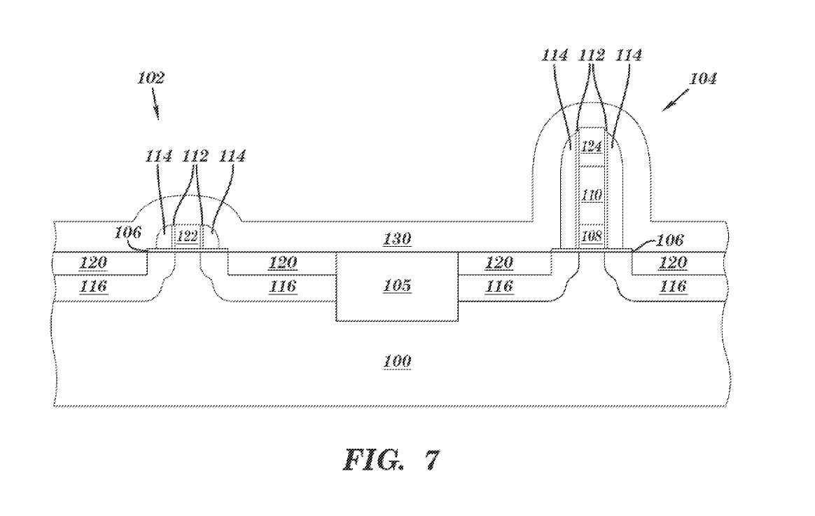

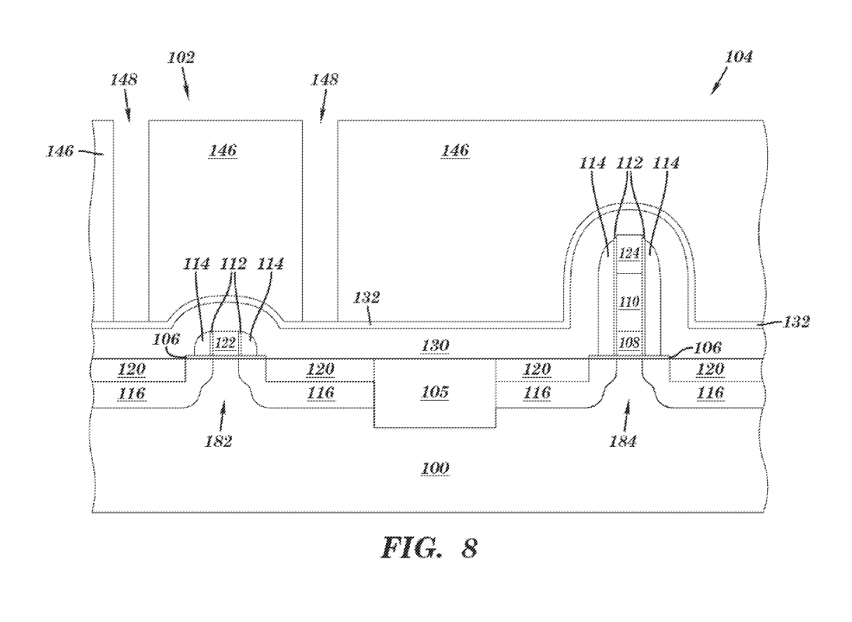

Referring to FIG. 7, a compressive nitride film 130 is deposited over the structure. The thickness of the compressive nitride film is preferably in the range 40-100 nm. The compressive nitride material 130 may be formed by high density plasma (HDP) deposition or plasma enhanced CVD (PECVD), for example, SiH₄/NH₃/N₂ at about 200° C. to about 500° C. This results in compressive stress being generated in the channels 182, 184 (FIG. 8) of the nMOSFET and pMOSFET regions 102, 104, respectively.

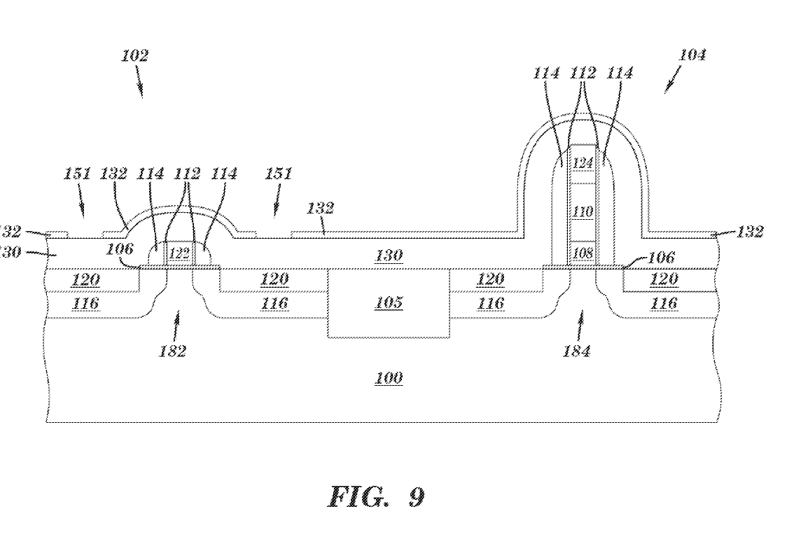

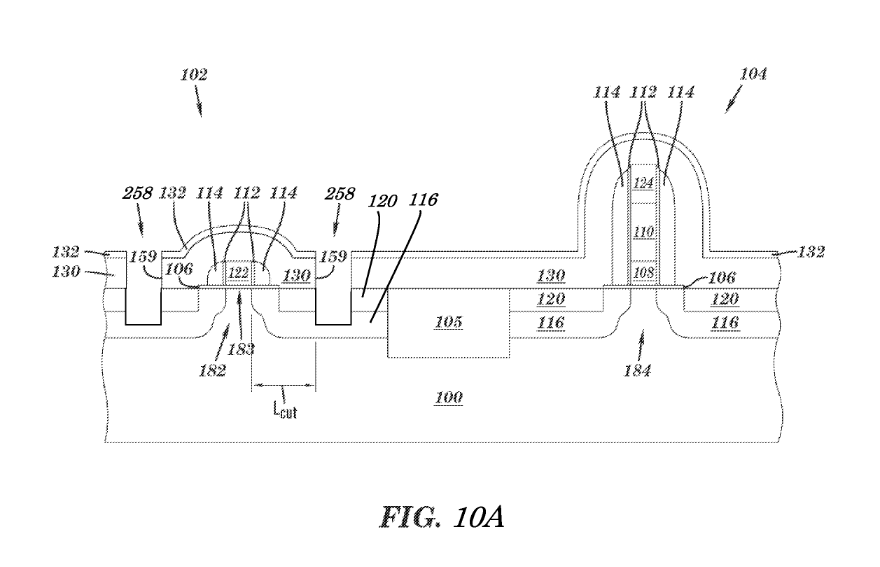

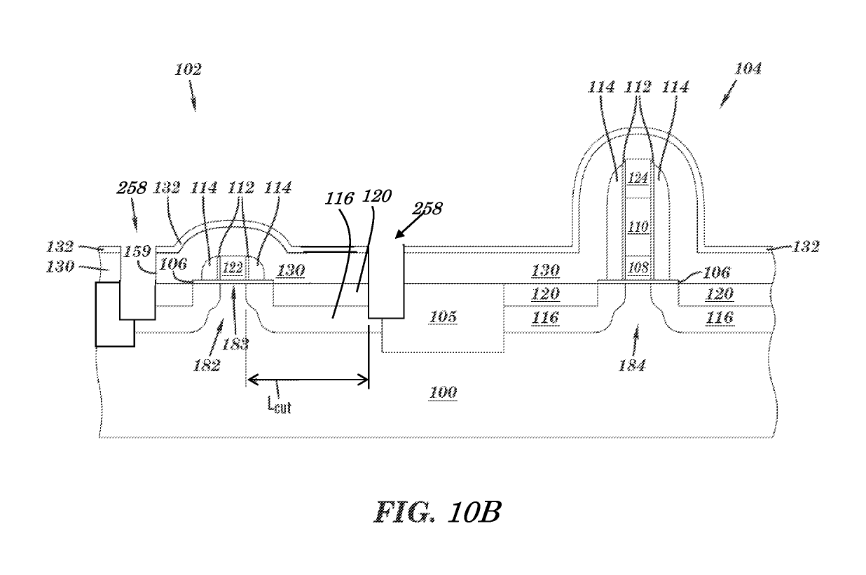

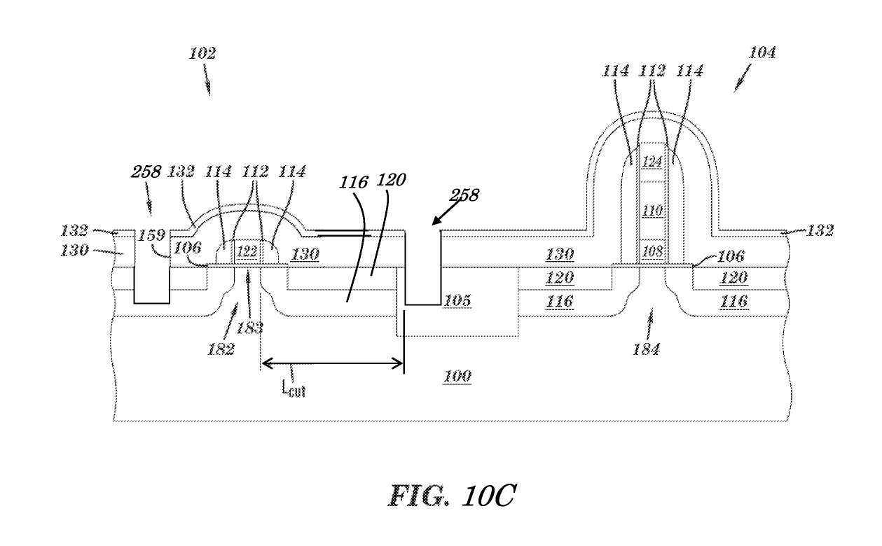

Next, a thin etch stop layer 132, such as an oxide, for example, about 50-100 angstroms thick, is formed atop the compressive nitride layer 130. Then, a photoresist material 146 is formed over the structure and thereafter patterned so as to form openings 148 in the resist 146 that expose the surface of the thin oxide 132 on at least opposite sides of the nMOSFET 102 over the source/drain regions 116, which will be used to pattern openings 158 in the compressive nitride layer 130 (see FIG. 10). For a sufficiently narrow width device, forming the opening 158 completely around the perimeter of the gate 122 in the compressive layer 130 may enhance device performance. However, for a wide width device, the additional benefit caused by surrounding the device by openings 158 is small, and it would be sufficient to form openings 158 on opposite sides of the shorter device 102. The exposed portion of the thin oxide layer 132 above the nMOSFET device 102 is removed to form openings 151 in the thin oxide 132, using a process such as by RIE for example, stopping on the compressive nitride layer 130. Then, resist layer 146 is removed. The resulting structure is illustrated in FIG. 9.

Next, as shown in FIGS. 10A-C, the compressive nitride layer 130 is removed, for example, by an isotropic or wet etch, where the openings in the thin oxide 132 has been formed over the source/drain regions 116 of the nMOSFET device 102, to form openings 258 so that an inner edge 159 of the opening 258 is at a horizontal distance Lcut from the outer edge of the gate conductor 122, so that the stress of the channel region 182 of the nMOSFET device 102 is modified to become tensile stress. In contrast to U.S. Pat. No. 7,183,613, however, as shown in FIGS. 10A-10C, opening 258 may extend into an underlying layer, e.g., 105, 116, 120. For example, as shown in FIG. 10A, opening 258 extends through silicide region 120 and into source/drain regions 116. Alternatively, as shown in FIG. 10B, opening 258 may extend at least partially into isolation region 105. Where opening 258 extends partially into isolation region 105, it also extends partially into source/drain regions 116. FIG. 10C shows opening 258 extending wholly within isolation region 105. It is noted that the width of the opening 258 may be from about 30 nm to about 100 nm, but is not critical, and that the edge of the opening 258 away from the gate stack may extend as far as the isolation region 105.

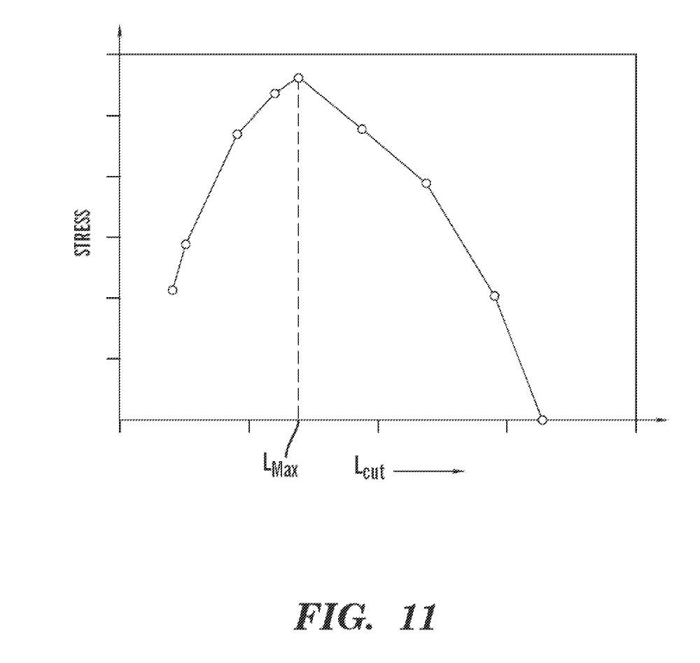

The preferred horizontal distance Lcut of the opening 258 from the gate conductor 122 is preferably selected so as to optimize the resulting stress in the channel region 182. This optimal distance L_{Max} can be determined, for example, by simulating the stress at the center 183 (FIG. 10C) of the channel region 182 for a range of expected gate structures similar to that of nMOSFET device 102, but varying the Lcut distance, and then determining the position of Lcut (i.e. L_{Max}) to be such that the channel stress is the maximized, as illustrated in FIG. 11. For the case of a pMOSFET that is shorter than the nMOSFET, the initial stressing layer 130 is tensile, and the value of Lcut is preferably chosen at Lₘₐₓ to maximize the compressive stress in the pMOSFET channel.

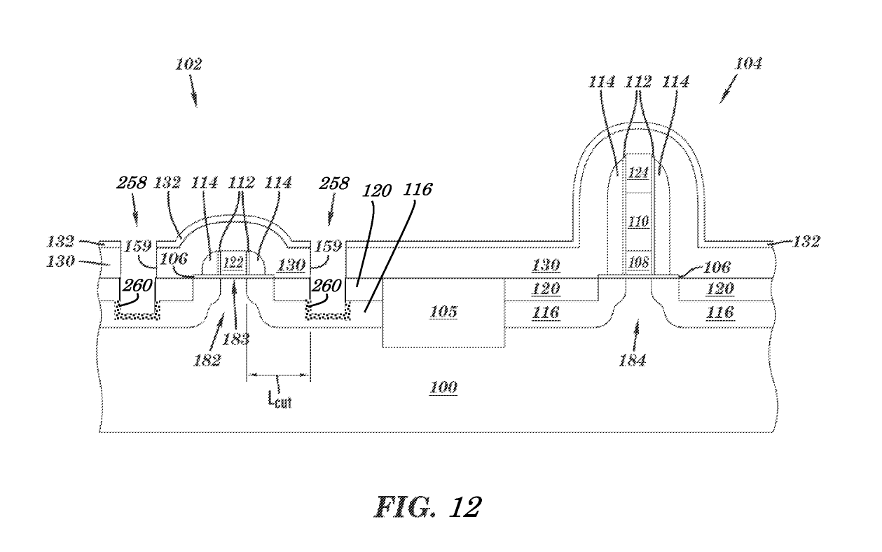

Next, as illustrated in FIG. 12, in one alternative embodiment, a thin metal layer may be deposited over the structure. For example, in a preferred embodiment, nickel is deposited at a thickness between about 2 and 10 nm, sufficient to silicide sidewalls and bottom of opening 258 in the source/drain regions 116 adjacent the nMOSFET gate stack 102. After an anneal, for example, at 300-500° C. at 1-60 seconds, a semiconductor metal alloy is formed from the metal and the silicon of the nMOSFET gate stack 102, the silicon of SOI layer 101 (FIG. 1 only) or substrate 100. The resulting structure includes silicide regions 260 in a bottom of openings 258, which assist in reducing contact resistance. After the anneal, a wet etch is performed to remove the un-reacted metal layer. If all of opening 258 is within isolation region 105 (FIG. 10C), above-mentioned processes are not necessary and can be skipped.

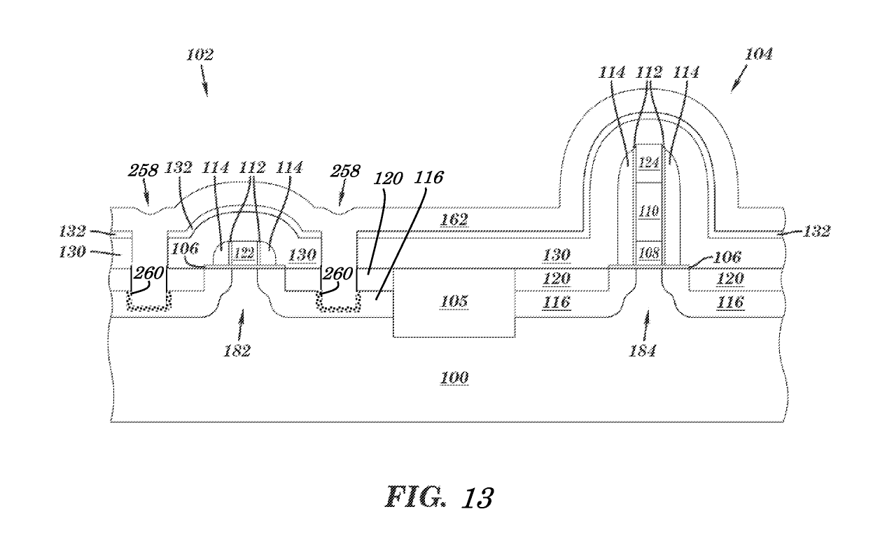

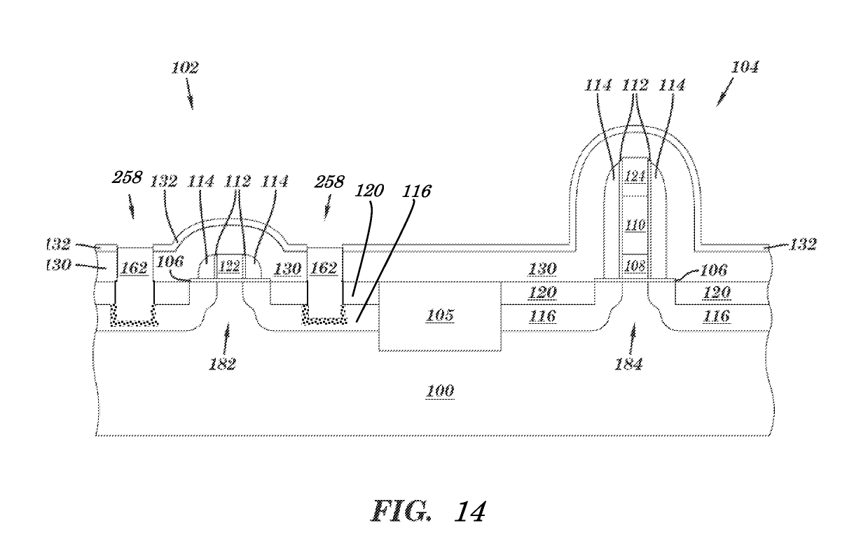

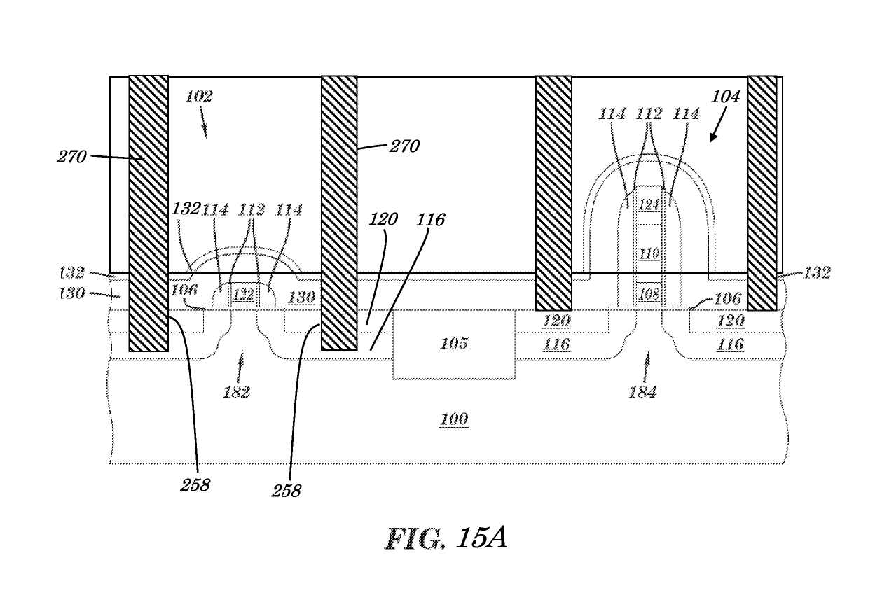

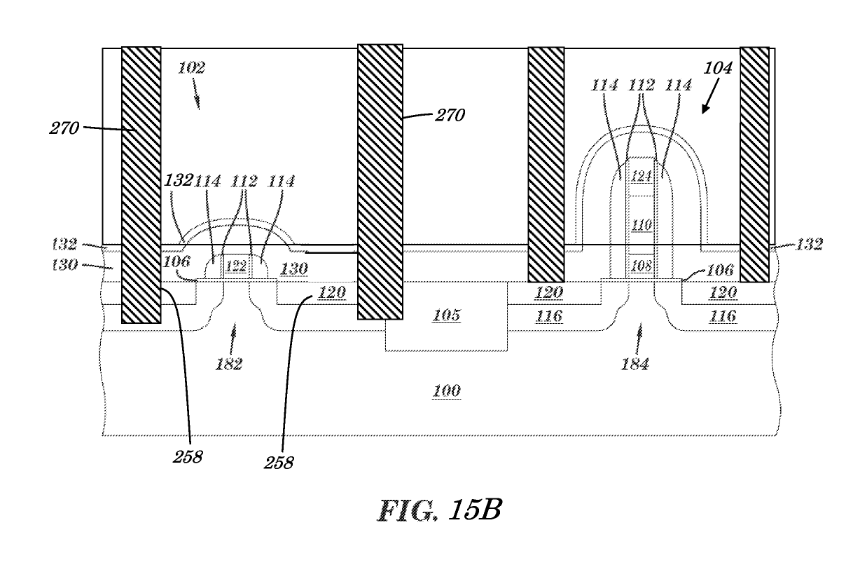

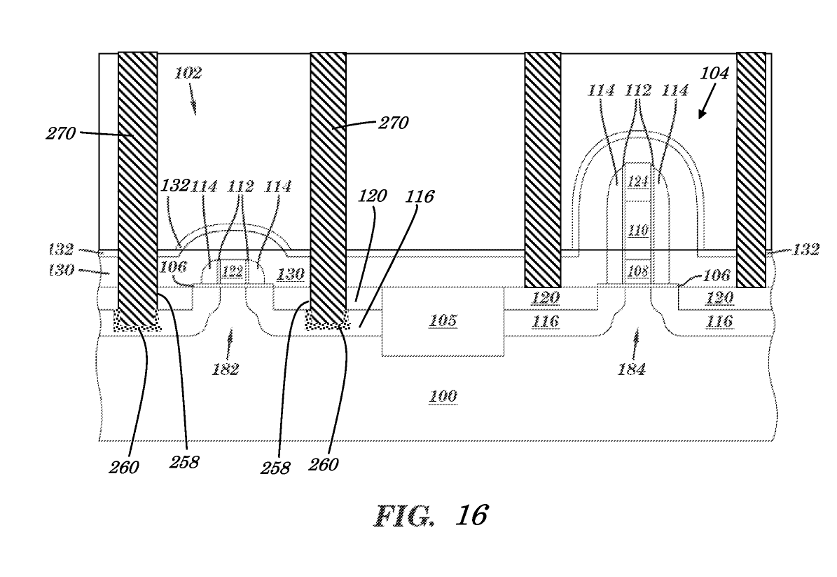

Referring to FIG. 13, next, a nitride film 162 having substantially neutral stress, or substantially without a large stress component is deposited over the structure, for example, by chemical vapor deposition (CVD) or high density plasma (HDP), so that the openings 158 are filled in the compressive nitride layer 130, as illustrated in FIG. 13. Preferably the thickness of the neutral stress layer 162 should be greater than ½ of the width of the opening 158. Then the neutral stress layer 162 is etched back to a surface that is substantially level with the surface of the thin oxide layer 132, as illustrated in FIG. 14. Subsequently, as illustrated in FIGS. 15A-B, the nMOSFET device 102 and pMOSFET device 104 may be completed as known by one skilled in the art. As part of this process, also illustrated in FIGS. 15A-B, contacts 270 may be formed at least partially within source/drain regions 116 in openings 258. FIG. 15A shows contact 270 wholly within source/drain regions 116, and FIG. 15B shows contact 270 partially within isolation region 105. FIGS. 15A-B show the structure without silicide regions 260 (FIG. 14). Alternatively, as illustrated in FIG. 16, as part of this process, contacts 270 may be formed to source/drain regions 116 including silicide regions 260. In this case, contacts 270 exhibit reduced resistance due to the presence of silicide regions 260 in openings 258. FIG. 16 shows silicide regions 260 applied only to the FIG. 15A embodiment, however, it is understood that silicide regions 260 are equally applicable to the FIG. 15B embodiment.

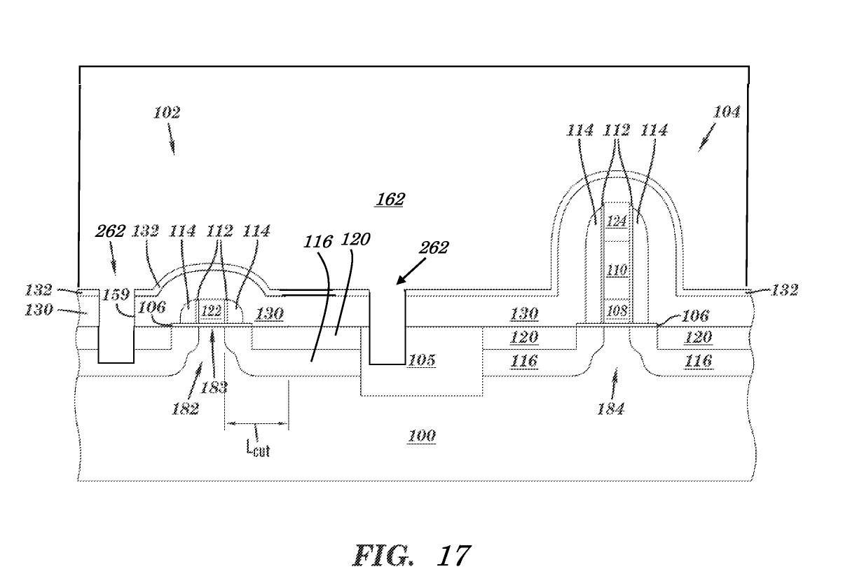

FIG. 17 shows opening 258 of the FIG. 10C embodiment in which all of opening 258 is within isolation region 105 and is filled with neutral stress layer 162. Although shown as a thicker layer in FIG. 17, neutral stress layer 162 may be a thinner layer, as shown in FIG. 13. As a result, a dielectric plug 262 that extends into underlying layer(s) of compressive nitride layer 130 is formed in openings 258 (FIG. 12). Etching to remove neutral stress layer 162 other than in dielectric plug 262 may be performed, if necessary. In this case, the above-mentioned processes for forming contacts 270 would not necessary and can be skipped. Alternatively, if desired, contacts 270 may be used in combination with dielectric plugs 262.

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A semiconductor structure comprising:
a first MOSFET device of a first type including a first gate conductor stack of first height over a first channel region, said first channel region under stress of a first type, wherein said first gate stack is overlain by a first stressing material causing said stress of a first type; and
a second MOSFET device of a second type including a second gate conductor stack over a second channel region, said second gate stack having a height less than said first height, and a second channel region under said second gate stack under stress of a second type, wherein said second gate stack is overlain by a second stressing material causing a stress of a second type different than said stress of said first type,
wherein said second stressing material is delimited by at least one discontinuity extending through said second stressing material into at least one underlying layer, said discontinuity separating said second stressing material from said first stressing material.

2. The semiconductor structure of claim 1 wherein said second stressing material and said first stressing material consist of substantially the same composition.

3. The semiconductor structure of claim 1 wherein said at least one discontinuity extending through said second stressing material is located at a distance from said second gate stack so that said stress of a second type is maximized in said second channel region.

4. The semiconductor structure of claim 1 wherein said at least one discontinuity extending through said second stressing material is at least on opposite sides of said second gate stack.

5. The semiconductor structure of claim 1 wherein said at least one discontinuity includes a contact extending through a silicide region of a source/drain region of said second gate stack.

6. The semiconductor structure of claim 5 wherein the at least one contact includes a silicided region in a bottom thereof in the source/drain region.

7. The semiconductor structure of claim 1 wherein said at least one discontinuity includes a dielectric plug extending at least partially into an isolation region.

8. The semiconductor structure of claim 7, wherein the dielectric plug extends partially into the isolation region and partially into a source/drain region of said second gate stack.

9. The semiconductor structure of claim 1 wherein said at least one discontinuity provides a spacing between said second stressing material and said first stressing material.

10. The semiconductor structure of claim 1 wherein said first type of MOSFET device is a pMOSFET and said stress of a first type is compressive and wherein said second type of MOSFET device is an nMOSFET and said stress of a second type is tensile.

11. The semiconductor structure of claim 1 wherein said first type of MOSFET device is an nMOSFET and said stress of a first type is tensile and wherein said second type of MOSFET device is an pMOSFET and said stress of a second type is compressive.

12. A method of forming a semiconductor structure comprising:
providing first and second gate stacks disposed adjacent one another on a substrate, wherein said first gate stack has a first height and said second gate stack has a second height less than said first height;
forming a stressing layer over said first and second gate stacks so that a stress of a first type is formed in the substrate under said first and said second gate stacks; and
forming an opening in said stressing layer at a distance from said second gate stack and into an underlying layer of said stressing layer so that a stress of a second type is formed in the substrate under said second gate conductor while said stress of said first type remains under said first gate stack.

13. The method of claim 12 wherein said opening extends into a source/drain region adjacent said second gate stack, and further comprising:
forming a silicide region in a bottom of the opening; and
forming a contact to the silicide region.

14. The method of claim 12 wherein said opening extends at least partially into an isolation region, and further comprising forming a dielectric plug in the opening.

15. The method of claim 14 wherein the dielectric plug extends partially into the isolation region and partially into a source/drain region of said second gate stack.

16. The method of claim 12 wherein said stress of a first type is compressive and said stress of a second type is tensile.

17. The method of claim 12 wherein said stress of a first type is tensile and said stress of a second type is compressive.

18. The method of claim 12 wherein said distance is located so that said stress of said second type is maximized.

19. A semiconductor structure comprising:
a first MOSFET device of a first type including a first gate conductor stack of first height over a first channel region, said first channel region under stress of a first type, wherein said first gate stack is overlain by a first stressing material causing said stress of a first type; and
a second MOSFET device of a second type including a second gate conductor stack over a second channel region, said second gate stack having a height less than said first height, and a second channel region under said second gate stack under stress of a second type, wherein said second gate stack is overlain by a second stressing material causing a stress of a second type different than said stress of said first type,
wherein said second stressing material is delimited by at least one discontinuity forming contact extending through said second stressing material into at least one underlying layer, said discontinuity forming contact separating said second stressing material from said first stressing material,
wherein said discontinuity forming contact extends through a silicide region of a source/drain region of said second gate stack.

20. The semiconductor structure of claim 19 wherein the at least one contact includes a silicided region in a bottom thereof in the source/drain region.
